(19) United States
(12) Patent Application Publication
(10) Pub. No.: US 2025/0223231 A1
(43) Pub. Date: Jul. 10, 2025

(54) GLASS-CERAMIC COMPOSITION, GLASS-CERAMIC SINTERED BODY, AND ELECTRONIC COMPONENT

(71) Applicant: Murata Manufacturing Co., Ltd., Nagaokakyo-shi (JP)

(72) Inventors: Hiroaki YAMADA, Nagaokakyo-shi (JP); Seiji FUJITA, Nagaokakyo-shi (JP)

(21) Appl. No.: 19/055,646

(22) Filed: Feb. 18, 2025

Related U.S. Application Data
(63) Continuation of application No. PCT/JP2023/028866, filed on Aug. 8, 2023.

(30) Foreign Application Priority Data
Aug. 25, 2022 (JP) 2022-134314

(51) Int. Cl. C04B 35/49; C04B 35/64; H03H 7/01

(52) U.S. Cl. CPC C04B 35/49; C04B 35/64; C04B 2235/3217; C04B 2235/3236; C04B 2235/3244; C04B 2235/365; C04B 2235/442; H03H 7/0115

(57) ABSTRACT

A glass-ceramic composition containing glass containing Li₂O, MgO, SrO, B₂O₃, SiO₂, and ZnO, and aggregates. Relative to 100% by weight of the glass-ceramic composition, a content of the glass is 9% by weight to 14% by weight, and the aggregates include 80% by weight to 86% by weight of ZrO₂, 2% by weight to 6% by weight of CaTiO₃, and 1% by weight to 4% by weight of at least one of BaCO₃ or Al₂O₃.

### CROSS REFERENCE TO RELATED APPLICATIONS

The present application is a continuation of International application No. PCT/JP2023/028866, filed Aug. 8, 2023, which claims priority to Japanese Patent Application No. 2022-134314, filed Aug. 25, 2022, the entire contents of each of which are incorporated herein by reference.

### TECHNICAL FIELD

The present disclosure relates to glass-ceramic compositions, glass-ceramic sintered bodies, and electronic components.

### BACKGROUND ART

For example, Patent Literature 1 discloses a glass-ceramic composition that can be fired at a temperature of 1000° C. or lower to form a sintered body having a low relative dielectric constant, a small temperature coefficient of resonance frequency, a small change in capacitance before and after a loading test, a high Qf value, high electrical insulating reliability, and a high flexural strength. The glass-ceramic composition is for forming glass-ceramic layers laminated on each other in a multilayer ceramic substrate. The glass-ceramic composition includes a first ceramic powder containing forsterite as a main component; a second ceramic powder containing SrTiO₃ and/or TiO₂ as a main component; a third ceramic powder containing BaZrO₃ as a main component; a fourth ceramic powder containing SrZr₃ as a main component; and a borosilicate glass powder containing Li₂O, MgO, B₂O₃, SiO₂, and ZnO, and at least one selected from CaO, BaO, and SrO.

Patent Literature 1: WO 2009/113475

### SUMMARY OF THE DISCLOSURE

A glass-ceramic sintered body obtained by firing the glass-ceramic composition disclosed in Patent Literature 1, however, has a low relative permittivity (εᵣ), which makes it difficult to miniaturize electronic components, in particular, filters such as LC filters, using the glass-ceramic sintered body.

The present disclosure is made to solve the above problem. The present disclosure aims to provide a glass-ceramic composition that can be fired at a temperature of 1000° C. or lower and forms a sintered body with a high relative permittivity, a high Qf value, and a small rate of change of capacitance. The present disclosure also aims to provide a glass-ceramic sintered body with a high relative permittivity, a high Qf value, and a small rate of change of capacitance. In addition, the present disclosure aims to provide an electronic component including a glass-ceramic layer made of a glass-ceramic sintered body formed by firing the glass-ceramic composition above or a glass-ceramic layer made of the glass-ceramic sintered body above.

A first embodiment of the present disclosure relates to a glass-ceramic composition containing glass containing Li₂O, MgO, SrO, B₂O₃, SiO₂, and ZnO, and aggregates, wherein, relative to 100% by weight of the glass-ceramic composition, a content of the glass is 9% by weight to 14% by weight, and the aggregates include 80% by weight to 86% by weight of ZrO₂, 2% by weight to 6% by weight of CaTiO₃, and 1% by weight to 4% by weight of at least one of BaCO₃ or Al₂O₃.

A second embodiment of the present disclosure relates to a glass-ceramic sintered body containing Zr, Ca, Ti, Ba, Li, Mg, Sr, B, Si, and Zn, wherein the glass-ceramic sintered body has a ZrO₂ content of 80% by weight to 86% by weight, a CaTiO₃ content of 2% by weight to 6% by weight, a BaO content of 0.78% by weight to 3.14% by weight, a Li₂O content of 0.3% by weight to 1.5% by weight, a MgO content of 2% by weight to 5% by weight, a SrO content of 0.5% by weight to 2.5% by weight, a B₂O₃ content of 1.5% by weight to 3% by weight, a SiO₂ content of 1% by weight to 3.5% by weight, and a ZnO content of 0.6% by weight to 2% by weight.

A third embodiment of the present disclosure relates to a glass-ceramic sintered body containing Zr, Ca, Ti, Al, Li, Mg, Sr, B, Si, and Zn, wherein the glass-ceramic sintered body has a ZrO₂ content of 80% by weight to 86% by weight, a CaTiO₃ content of 2% by weight to 6% by weight, an Al₂O₃ content of 1% by weight to 4% by weight, a Li₂O content of 0.3% by weight to 1.5% by weight, a MgO content of 2% by weight to 5% by weight, a SrO content of 0.5% by weight to 2.5% by weight, a B₂O₃ content of 1.5% by weight to 3% by weight, a SiO₂ content of 1% by weight to 3.5% by weight, and a ZnO content of 0.6% by weight to 2% by weight.

A fourth embodiment of the present disclosure relates to a glass-ceramic sintered body containing Zr, Ca, Ti, Ba, Al, Li, Mg, Sr, B, Si, and Zn, wherein the glass-ceramic sintered body has a ZrO₂ content of 80% by weight to 86% by weight, a CaTiO₃ content of 2% by weight to 6% by weight, a BaO content of 0.78% by weight to 2.35% by weight, an Al₂O₃ content of 1% by weight to 3.01% by weight, a Li₂O content of 0.3% by weight to 1.5% by weight, a MgO content of 2% by weight to 5% by weight, a SrO content of 0.5% by weight to 2.5% by weight, a B₂O₃ content of 1.5% by weight to 3% by weight, a SiO₂ content of 1% by weight to 3.5% by weight, and a ZnO content of 0.6% by weight to 2% by weight.

A fifth embodiment of the present disclosure relates to an electronic component including a glass-ceramic layer made of a glass-ceramic sintered body formed by firing the glass-ceramic composition according to the first embodiment of the present disclosure.

A sixth embodiment of the present disclosure relates to an electronic component including a glass-ceramic layer made of the glass-ceramic sintered body according to any of the second to fourth embodiments.

The present disclosure can provide a glass-ceramic composition that can be fired at a temperature of 1000° C. or lower and forms a sintered body with a high relative permittivity, a high Qf value, and a small rate of change of capacitance. The present disclosure can also provide a glass-ceramic sintered body with a high relative permittivity, a high Qf value, and a small rate of change of capacitance. In addition, the present disclosure can provide an electronic component including a glass-ceramic layer made of a glass-ceramic sintered body formed by firing the glass-ceramic composition above or a glass-ceramic layer made of the glass-ceramic sintered body above.

### BRIEF DESCRIPTION OF THE DRAWINGS

FIG. 1 is a perspective view showing the appearance of an LC filter as an example of the electronic component according to the fifth or sixth embodiment of the present disclosure.

FIG. 2 is an equivalent circuit diagram of the LC filter shown in FIG. 1.

FIG. 3 is an exploded perspective view of a raw laminate as an intermediate product to be fired in production of the LC filter shown in FIG. 1.

### DESCRIPTION OF THE PREFERRED EMBODIMENTS

Hereinafter, the glass-ceramic composition, the glass-ceramic sintered body, and the electronic component of the present disclosure are described. The present disclosure is not limited to the following preferred embodiments and may be suitably modified without departing from the gist of the present disclosure. Combinations of two or more preferred features described in the following preferred embodiments are also within the scope of the present disclosure.

### Glass-Ceramic Composition

The glass-ceramic composition according to the first embodiment of the present disclosure is a low temperature co-fired ceramic (LTCC) material, which is capable of being sintered at a firing temperature of 1000° C. or lower.

Specifically, the glass-ceramic composition according to the first embodiment contains glass containing Li₂O, MgO, SrO, B₂O₃, SiO₂, and ZnO, and aggregates. Relative to 100% by weight of the glass-ceramic composition, a content of the glass is 9% by weight to 14% by weight, and the aggregates include 80% by weight to 86% by weight of ZrO₂, 2% by weight to 6% by weight of CaTiO₃, and 1% by weight to 4% by weight of at least one of BaCO₃ or Al₂O₃.

Such a glass-ceramic composition can be fired at a temperature of 1000° C. or lower and form a sintered body with a high relative permittivity (hereinafter, abbreviated as εᵣ), a high Qf value, and a small rate of change of capacitance (hereinafter, abbreviated as TCC).

Specifically, such a glass-ceramic composition can be fired at a temperature of 1000° C. or lower and form a sintered body with an εᵣ of 15 or higher (for example, 15.2 to 17.9), a Qf value of 10000 GHz or higher (for example, 10000 to 22000 GHz), and an absolute value of the TCC falling within a temperature range of −40° C. to 85° C. of 75 ppm/° C. or less (for example, −60 to 75 ppm/° C.).

Use of this material enables production of a miniaturized electronic component such as an LC filter while maintaining a low insertion loss.

The TCC and the temperature coefficient of resonance frequency If are each a temperature characteristic and represent the relationship expressed by the following formula:

$$TCC = - 2 ( {τ}_{f} + α )$$

wherein α is a coefficient of thermal expansion.

The glass-ceramic composition contains the components above in powdered form. In other words, a glass-ceramic composition contains a first ceramic powder containing ZrO₂ as its main component, a second ceramic powder containing CaTiO₃ as its main component, a third ceramic powder containing at least one of BaCO₃ or Al₂O₃ as its main component, and glass powder (borosilicate glass powder) containing Li₂O, MgO, SrO, B₂O₃, SiO₂, and ZnO.

The aggregates (fillers) and the glass are added for the following purposes.
ZrO₂: increases εᵣ and Qf value
CaTiO₃: increases εᵣ, adjusts TCC (shifts TCC to the negative side)
BaCO₃ and Al₂O₃: improves acid resistance of sintered body (suppresses crystallization of glass and prevents glass from becoming ZnO-rich glass which has low acid resistance)
Glass: allows sintering at lower temperatures

A ZrO₂ content of less than 80% by weight may decrease the εᵣ.

A ZrO₂ content of more than 86% by weight may deteriorate the sinterability of the glass-ceramic composition.

The ZrO₂ content is 80% by weight to 86% by weight, preferably 82% by weight to 85% by weight. The glass-ceramic composition with a ZrO₂ content of 82% by weight to 85% by weight can form a glass-ceramic sintered body with a higher εr and a higher Qf value (for example, an εᵣ of 16.3 or higher and a Qf value of 20000 or higher).

A CaTiO₃ content of less than 2% by weight may deteriorate the sinterability of the glass-ceramic composition.

A CaTiO₃ content of more than 6% by weight may increase the absolute value of the TCC (may increase the TCC to the negative side).

The CaTiO₃ content is 2% by weight to 6% by weight, preferably 4% by weight to 6% by weight. The glass-ceramic composition with a CaTiO₃ content of 4% by weight to 6% by weight can form a glass-ceramic sintered body with a higher εr and a higher Qf value (for example, an εᵣ of 16.3 or higher and a Qf value of 20000 or higher).

A content of at least one of BaCO₃ or Al₂O₃ of less than 1% by weight may deteriorate the acid resistance of the sintered body.

A content of at least one of BaCO₃ or Al₂O₃ of more than 4% by weight may decrease the Qf value while increasing the TCC, or may decrease the εᵣ.

The content of at least one of BaCO₃ or Al₂O₃ is 1% by weight to 4% by weight, preferably 18 by weight to 2% by weight. The glass-ceramic composition with a content of at least one of BaCO₃ or Al₂O₃ of 1% by weight to 2% by weight can form a glass-ceramic sintered body with a higher εᵣ and a higher Qf value (for example, an εᵣ of 16.3 or higher and a Qf value of 20000 or higher).

A glass content of less than 9% by weight may deteriorate the sinterability.

A glass content of more than 14% by weight may decrease the εᵣ.

The glass content is 9% by weight to 14% by weight, preferably 9% by weight to 10% by weight. The glass-ceramic composition with a glass content of 9% by weight to 10% by weight can form a glass-ceramic sintered body with a higher εr and a higher Qf value (for example, an εᵣ of 16.3 or higher and a Qf value of 20000 or higher).

In the glass, the Li₂O content is preferably 3% by weight to 15% by weight, the MgO content is preferably 20% by weight to 50% by weight, the SrO content is preferably 5% by weight to 25% by weight, the B₂O₃ content is preferably 15% by weight to 30% by weight, the SiO₂ content is preferably 10% by weight to 35% by weight, and the ZnO content is preferably 6% by weight to 20% by weight.

A Li₂O content of less than 3% by weight may deteriorate the sinterability of the glass-ceramic composition.

A Li₂O content of more than 15% by weight may deteriorate the acid resistance of the sintered body.

The Li₂O content is preferably 3% by weight to 15% by weight, more preferably 3% by weight to 7% by weight, still more preferably substantially 5% by weight. The glass-ceramic composition with a Li₂O content of 3% by weight to 7% by weight can form a glass-ceramic sintered body with a higher εr and a higher Qf value (for example, an εᵣ of 16.1 or higher and a Qf value of 18000 or higher).

A MgO content of less than 20% by weight may decrease the Qf value.

A MgO content of more than 50% by weight may cause partial crystallization of the glass, i.e., devitrification.

The MgO content is preferably 20% by weight to 50% by weight, more preferably 25% by weight to 50% by weight. The glass-ceramic composition with a MgO content of 25% by weight to 50% by weight can form a glass-ceramic sintered body with a higher εr and a higher Qf value (for example, an εᵣ of 16.1 or higher and a Qf value of 18000 or higher).

A SrO content of less than 5% by weight may cause devitrification.

A SrO content of more than 25% by weight may decrease the Qf value.

The SrO content is preferably 5% by weight to 25% by weight, more preferably 5% by weight to 17.5% by weight. The glass-ceramic composition with a SrO content of 5% by weight to 17.5% by weight can form a glass-ceramic sintered body with a higher εr and a higher Qf value (for example, an εᵣ of 16.1 or higher and a Qf value of 18000 or higher).

A B₂O₃ content of less than 15% by weight may cause devitrification.

A B₂O₃ content of more than 30% by weight may deteriorate the acid resistance of the sintered body.

The B₂O₃ content is preferably 15% by weight to 30% by weight, more preferably 15% by weight to 20% by weight. The glass-ceramic composition with a B₂O₃ content of 15% by weight to 20% by weight can form a glass-ceramic sintered body with a higher εr and a higher Qf value (for example, an εᵣ of 16.1 or higher and a Qf value of 18000 or higher).

A SiO₂ content of less than 10% by weight may cause devitrification.

A SiO₂ content of more than 35% by weight may deteriorate the sinterability of the glass-ceramic composition.

The SiO₂ content is preferably 10% by weight to 35% by weight, more preferably 15% by weight to 25% by weight. The glass-ceramic composition with a SiO₂ content of 15% by weight to 25% by weight can form a glass-ceramic sintered body with a higher εr and a higher Qf value (for example, an εᵣ of 16.1 or higher and a Qf value of 18000 or higher).

A ZnO content of less than 6% by weight may decrease the Qf value.

A ZnO content of more than 20% by weight may deteriorate the acid resistance of the sintered body.

The ZnO content is preferably 6% by weight to 20% by weight, more preferably 6% by weight to 9% by weight, still more preferably substantially 7.5% by weight. The glass-ceramic composition with a ZnO content of 6% by weight to 9% by weight can form a glass-ceramic sintered body with a higher εr and a higher Qf value (for example, an εᵣ of 16.1 or higher and a Qf value of 18000 or higher).

Glass-ceramic Sintered Body

The glass-ceramic sintered body according to the second embodiment of the present disclosure is a glass-ceramic sintered body containing Zr, Ca, Ti, Ba, Li, Mg, Sr, B, Si, and Zn, wherein the glass-ceramic sintered body has a ZrO₂ content of 80% by weight to 86% by weight, a CaTiO₃ content of 2% by weight to 6% by weight, a BaO content of 0.78% by weight to 3.14% by weight, a Li₂O content of 0.3% by weight to 1.5% by weight, a MgO content of 2% by weight to 5% by weight, a SrO content of 0.5% by weight to 2.5% by weight, a B₂O₃ content of 1.5% by weight to 3% by weight, a SiO₂ content of 1% by weight to 3.5% by weight, and a ZnO content of 0.6% by weight to 2% by weight.

The glass-ceramic sintered body according to the third embodiment of the present disclosure is a glass-ceramic sintered body containing Zr, Ca, Ti, Al, Li, Mg, Sr, B, Si, and Zn, wherein the glass-ceramic sintered body has a ZrO₂ content of 80% by weight to 86% by weight, a CaTiO₃ content of 2% by weight to 6% by weight, an Al₂0₃ content of 1% by weight to 4% by weight, a Li₂O content of 0.3% by weight to 1.5% by weight, a MgO content of 2% by weight to 5% by weight, a SrO content of 0.5% by weight to 2.5% by weight, a B₂O₃ content of 1.5% by weight to 3% by weight, a SiO₂ content of 1% by weight to 3.5% by weight, and a ZnO content of 0.6% by weight to 2% by weight.

The glass-ceramic sintered body according to the fourth embodiment of the present disclosure is a glass-ceramic sintered body containing Zr, Ca, Ti, Ba, Al, Li, Mg, Sr, B, Si, and Zn, wherein the glass-ceramic sintered body has a ZrO₂ content of 80% by weight to 86% by weight, a CaTiO₃ content of 2% by weight to 6% by weight, a BaO content of 0.78% by weight to 2.35% by weight, an Al₂O₃ content of 1% by weight to 3.01% by weight, a Li₂O content of 0.3% by weight to 1.5% by weight, a MgO content of 2% by weight to 5% by weight, a SrO content of 0.5% by weight to 2.5% by weight, a B₂O₃ content of 1.5% by weight to 3% by weight, a SiO₂ content of 1% by weight to 3.5% by weight, and a ZnO content of 0.6% by weight to 2% by weight.

The glass-ceramic sintered bodies according to the second to fourth embodiments can materialize a glass-ceramic sintered body with a high relative permittivity, a high Qf value, and a small rate of change of capacitance.

Specifically, such a glass-ceramic sintered body can achieve an εᵣ of 15 or higher (for example, 15.2 to 17.9), a Qf value of 10000 GHz or higher (for example, 10000 to 22000 GHz), and an absolute value of the TCC falling within a temperature range of −40° C. to 85° C. of 75 ppm/° C. or less (for example, −60 to 75 ppm/° C.).

Use of this material enables production of a miniaturized electronic component such as an LC filter while maintaining a low insertion loss.

The glass-ceramic sintered bodies according to the second to fourth embodiments can each be produced by firing the glass-ceramic composition according to the first embodiment at a temperature of 1000° C. or lower. The purposes of adding the components, the critical meaning of the contents, and the preferred ranges, for example, in the case of the glass-ceramic sintered bodies according to the second to fourth embodiments are the same as those in the case of the glass-ceramic composition according to the first embodiment, and are thus omitted here.

The BaCO₃ content decreases by the amount of CO₂ since BaCO₃ exists as BaO after firing.

Thus, in the glass-ceramic sintered body according to the second embodiment of the present disclosure, the BaO content is 0.78% by weight to 3.14% by weight, preferably 0.78% by weight to 1.56% by weight. With a BaO content of 0.78% by weight to 1.56% by weight, the glass-ceramic sintered body can achieve a higher εᵣ and a higher Qf value (for example, an εᵣ of 16.3 or higher and a Qf value of 20000 or higher).

In the glass-ceramic sintered body according to the third embodiment of the present disclosure, the Al₂O₃ content is 1% by weight to 4% by weight, preferably 1% by weight to 2% by weight. With an Al₂O₃ content of 1% by weight to 2% by weight, the glass-ceramic sintered body can achieve a higher εᵣ and a higher Qf value (for example, an εᵣ of 16.3 or higher and a Qf value of 20000 or higher).

In the glass-ceramic sintered body according to the fourth embodiment of the present disclosure, the BaO content is 0.78% by weight to 2.35% by weight, preferably 0.78% by weight to 1.56% by weight, more preferably 0.78% by weight to 1.5% by weight, still more preferably substantially 0.78% by weight, and the Al₂O₃ content is 1% by weight to 3.01% by weight, preferably 1% by weight to 2% by weight, more preferably 1% by weight to 1.5% by weight, more preferably substantially 1% by weight. With a BaO content of 0.78% by weight to 1.56% by weight and an Al₂O₃ content of 1% by weight to 2% by weight, the glass-ceramic sintered body can achieve a higher εᵣ and a higher Qf value (for example, an εᵣ of 16.3 or higher and a Qf value of 20000 or higher).

In the glass-ceramic sintered bodies according to the second to fourth embodiments of the present disclosure, the glass component contents and their preferred ranges are described as follows.

The Li₂O content is 0.3% by weight to 1.5% by weight, preferably 0.3% by weight to 0.7% by weight, preferably substantially 0.5% by weight. With a Li₂O content of 0.3% by weight to 0.7% by weight, the glass-ceramic sintered body can achieve a higher εᵣ and a higher Qf value (for example, an εᵣ of 16.1 or higher and a Qf value of 18000 or higher).

The MgO content is 2% by weight to 5% by weight, preferably 2.5% by weight to 5% by weight. With a MgO content of 2.5% by weight to 5% by weight, the glass-ceramic sintered body can achieve a higher εᵣ and a higher Qf value (for example, an εᵣ of 16.1 or higher and a Qf value of 18000 or higher).

The SrO content is 0.5% by weight to 2.5% by weight, preferably 0.5% by weight to 1.75% by weight. With a SrO content of 0.5% by weight to 1.75% by weight, the glass-ceramic sintered body can achieve a higher εᵣ and a higher Qf value (for example, an εᵣ of 16.1 or higher and a Qf value of 18000 or higher).

The B₂O₃ content is 1.5% by weight to 3% by weight, preferably 1.5% by weight to 2% by weight. With a B₂O₃ content of 1.5% by weight to 2% by weight, the glass-ceramic sintered body can achieve a higher εᵣ and a higher Qf value (for example, an εᵣ of 16.1 or higher and a Qf value of 18000 or higher).

The SiO₂ content is 1% by weight to 3.5% by weight, preferably 1.5% by weight to 2.5% by weight. With a SiO₂ content of 1.5% by weight to 2.5% by weight, the glass-ceramic sintered body can achieve a higher εᵣ and a higher Qf value (for example, an εᵣ of 16.1 or higher and a Qf value of 18000 or higher).

The ZnO content is 0.6% by weight to 2% by weight, preferably 0.6% by weight to 0.9% by weight, preferably substantially 0.75% by weight. With a ZnO content of 0.6% by weight to 0.9% by weight, the glass-ceramic sintered body can achieve a higher εᵣ and a higher Qf value (for example, an εᵣ of 16.1 or higher and a Qf value of 18000 or higher).

In the glass-ceramic sintered bodies according to the second to fourth embodiments, the glass containing Li₂O, MgO, SrO, B₂O₃, SiO₂, and ZnO is usually in an amorphous phase, and ZrO₂, CaTiO₃, BaO, and Al₂O₃ are usually in their respective ceramic particulate forms, i.e., as particulate crystalline phases.

In the glass-ceramic sintered bodies of the present disclosure, a distinction or separation can be made between the glass and the other components (aggregates) by a method including analyzing the electron diffraction pattern in a scanning electron microscope (SEM) or a transmission electron microscope (TEM) or by a method including dissolving the glass portion in hydrogen fluoride or the like.

The glass and the other components between which a distinction or separation has been made are subjected to elemental analysis such as wavelength dispersive X-ray analysis (WDX), energy dispersive X-ray analysis (EDX), or inductively coupled plasma optical emission spectrometry (ICP) to measure the compositions (contents) of the glass and the other components in terms of the oxides above.

In other words, the glass-ceramic sintered body according to the second embodiment of the present disclosure is synonymous with a glass-ceramic sintered body containing 80% by weight to 86% by weight of Zr in terms of ZrO₂, 2% by weight to 6% by weight of Ca and Ti in terms of CaTiO₃, 0.78% by weight to 3.14% by weight of Ba in terms of BaO, 0.3% by weight to 1.5% by weight of Li in terms of Li₂O, 2% by weight to 5% by weight of Mg in terms of MgO, 0.5% by weight to 2.5% by weight of Sr in terms of SrO, 1.5% by weight to 3% by weight of B in terms of B₂O₃, 1% by weight to 3.5% by weight of Si in terms of SiO₂, and 0.6% by weight to 2% by weight of Zn in terms of ZnO.

The glass-ceramic sintered body according to the third embodiment of the present disclosure is synonymous with a glass-ceramic sintered body containing 80% by weight to 86% by weight of Zr in terms of ZrO₂, 2% by weight to 6% by weight of Ca and Ti in terms of CaTiO₃, 1% by weight to 4% by weight of Al in terms of Al₂O₃, 0.3% by weight to 1.5% by weight of Li in terms of Li₂O, 2% by weight to 5% by weight of Mg in terms of MgO, 0.5% by weight to 2.5% by weight of Sr in terms of SrO, 1.5% by weight to 3% by weight of B in terms of B₂O₃, 1% by weight to 3.5% by weight of Si in terms of SiO₂, and 0.6% by weight to 2% by weight of Zn in terms of ZnO.

The glass-ceramic sintered body according to the fourth embodiment of the present disclosure is synonymous with a glass-ceramic sintered body containing 80% by weight to 86% by weight of Zr in terms of ZrO₂, 2% by weight to 6% by weight of Ca and Ti in terms of CaTiO₃, 0.78% by weight to 2.35% by weight of Ba in terms of BaO, 1% by weight to 3.01% by weight of Al in terms of Al₂O₃, 0.3% by weight to 1.5% by weight of Li in terms of Li₂O, 2% by weight to 5% by weight of Mg in terms of MgO, 0.5% by weight to 2.5% by weight of Sr in terms of SrO, 1.5% by weight to 3% by weight of B in terms of B₂O₃, 1% by weight to 3.5% by weight of Si in terms of SiO₂, and 0.6% by weight to 2% by weight of Zn in terms of ZnO.

In the glass-ceramic sintered bodies according to the second to fourth embodiments, the glass may be partially crystallized (aggregated) and the ceramic powders may be partially melted and incorporated into the amorphous phase of the glass.

In the glass-ceramic sintered bodies of the present disclosure, MgO and SiO₂ may be present in the form of Mg₂SiO₄ (forsterite) through partial reaction with each other by firing (see the reaction formula (1) below). In that case, the Mg₂SiO₄ content measured by any of the methods above is converted into the MgO content and the SiO₂ content, and the glass-ceramic sintered body is regarded as having the converted MgO and SiO₂ contents.

$$2 MgO + {SiO}_{2} ⇔ {Mg}_{2} {SiO}_{4} \qquad ( 1 )$$

### Electronic Component

The electronic component according to the fifth embodiment of the present disclosure includes a glass-ceramic layer made of a glass-ceramic sintered body formed by firing the glass-ceramic composition according to the first embodiment.

The electronic component according to the sixth embodiment of the present disclosure includes a glass-ceramic layer made of the glass-ceramic sintered body according to any of the second to fourth embodiments.

Thus, a miniaturized electronic component can be achieved.

The electronic component according to the sixth embodiment includes a glass-ceramic layer made of the glass-ceramic sintered body according to at least one of the second to fourth embodiments. For example, the electronic component may include only a (single-layered or multi-layered) glass-ceramic layer made of the glass-ceramic sintered body according to any one of the second to fourth embodiments. The electronic component may also include a multi-layered glass-ceramic layer made of the glass-ceramic sintered bodies according to two or more different embodiments among the second to fourth embodiments.

Specific suitable examples of the electronic component include, but are not limited to, filters such as band-pass filters. LC filters are particularly preferred.

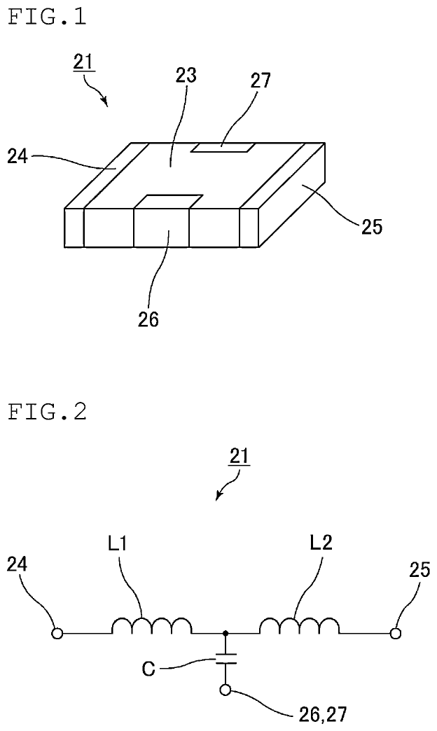

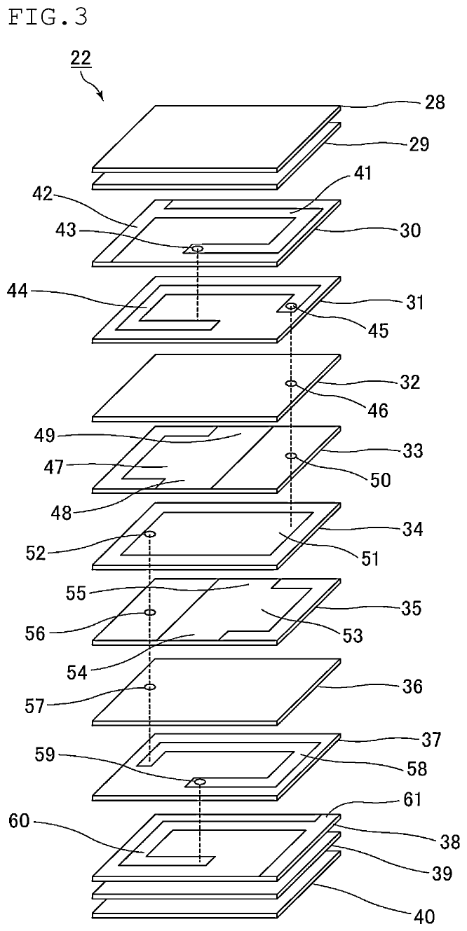

FIG. 1 is a perspective view showing the appearance of an LC filter as an example of the electronic component according to the fifth or sixth embodiment of the present disclosure. FIG. 2 is an equivalent circuit diagram of the LC filter shown in FIG. 1. FIG. 3 is an exploded perspective view of a raw laminate as an intermediate product to be fired in production of the LC filter shown in FIG. 1.

An LC filter 21, as shown in FIG. 1, includes a component body 23 as a laminate structure in which multiple glass-ceramic layers are stacked. The LC filter 21 also includes, on the outer surface of the component body 23, terminal electrodes 24 and 25 at the ends and terminal electrodes 26 and 27 in the middle portions of the side faces.

The LC filter 21, as shown in FIG. 2, includes coils exhibiting two inductance values L1 and L2 and connected in series between the terminal electrodes 24 and 25, and includes a capacitor exhibiting capacitance C between the connection point of the coils exhibiting inductance values L1 and L2 and each of the terminal electrodes 26 and 27.

FIG. 3 shows that a raw laminate 22 is to define the component body 23 through firing and includes a stack of multiple ceramic green sheets 28 to 40. The number of stacked ceramic green sheets is not limited to the number shown in the figure.

Each of the ceramic green sheets 28 to 40 is obtained by adding an organic vehicle made of a binder resin and a solvent to the glass-ceramic composition according to the first embodiment of the present disclosure, mixing them to obtain a ceramic slurry, molding the ceramic slurry into a sheet by doctor-blading, drying the sheet, and punching the sheet to a predetermined size.

To achieve the inductance values L1 and L2 and the capacitance C as shown in FIG. 2, wiring conductors are provided in the embodiment below for specific ceramic green sheets among the ceramic green sheets 28 to 40.

On the ceramic green sheet 30, a coil pattern 41 constituting part of the coils exhibiting the inductance value L1 is formed. A lead-out pattern 42 extends from one end of the coil pattern 41. A via hole conductor 43 is formed in the other end of the coil pattern 41.

On the ceramic green sheet 31, a coil pattern 44 constituting part of the coils exhibiting the inductance value L1 is formed. A via hole conductor 45 is formed in one end of the coil pattern 44, and the other end of the coil pattern 44 is connected to the via hole conductor 43 above.

The ceramic green sheet 32 has a via hole conductor 46 connected to the via hole conductor 45 above.

On the ceramic green sheet 33, a capacitor pattern 47 constituting part of the capacitor exhibiting the capacitance C is formed. Lead-out patterns 48 and 49 extend from the capacitor pattern 47. In the ceramic green sheet 33, a via hole conductor 50 connected to the via hole conductor 46 above is also formed.

On the ceramic green sheet 34, a capacitor pattern 51 constituting part of the capacitor exhibiting the capacitance C and a via hole conductor 52 connected to the capacitor pattern 51 are formed. The capacitor pattern 51 is connected to the via hole conductor 50 above.

On the ceramic green sheet 35, a capacitor pattern 53 constituting part of the capacitor exhibiting the capacitance C is formed. Lead-out patterns 54 and 55 extend from the capacitor pattern 53. In the ceramic green sheet 35, a via hole conductor 56 connected to the via hole conductor 52 above is also formed.

In the ceramic green sheet 36, a via hole conductor 57 connected to the via hole conductor 56 above is formed.

On the ceramic green sheet 37, a coil pattern 58 constituting part of the coils exhibiting the inductance value L2 is formed. A via hole conductor 59 is formed at one end of the coil pattern 58. The other end of the coil pattern 58 is connected to the via hole conductor 57 above.

On the ceramic green sheet 38, a coil pattern 60 constituting part of the coils exhibiting the inductance value L2 is formed. A lead-out pattern 61 extends from one end of the coil pattern 60. The other end of the coil pattern 60 is connected to the via hole conductor 59 above.

In formation of the coil patterns 41, 44, 58, and 60, lead-out patterns 42, 48, 49, 54, 55, and 61, via hole conductors 43, 45, 46, 50, 52, 56, 57, and 59, and capacitor patterns 47, 51, and 53 as the wiring conductors, a conductive paste containing copper or silver as its main component is used, and the conductive paste is provided by, for example, screen printing.

To obtain the raw laminate 22, the ceramic green sheets 28 to 40 are stacked in the order shown in FIG. 3 and pressed together in the thickness direction.

The raw laminate 22 is then fired at a temperature of 1000° C. or lower, such as a temperature of 800° C. to 1000° C., so that the component body 23 shown in FIG. 1 can be obtained. Here, the raw laminate is fired in a non-oxidizing atmosphere such as nitrogen atmosphere or a low oxygen atmosphere in the case where the wiring conductor contains copper as its main component. The raw laminate is fired in an oxidizing atmosphere such as air in the case where the wiring conductor contains silver as its main component. The firing atmosphere may be a reducing atmosphere.

Next, the terminal electrodes 24 to 27 are formed on the outer surface of the component body 23. These terminal electrodes 24 to 27 are formed, for example, by application of a conductive paste containing copper or silver as its main component, followed by baking, or by a thin film formation method such as vapor deposition, plating, or sputtering.

The LC filter 21 is obtainable by the procedure described above. This LC filter 21 includes the ceramic green sheets 28 to 40 each obtained using the glass-ceramic composition according to the first embodiment of the present disclosure, i.e., includes the ceramic green sheets 28 to 40 each made of the glass-ceramic sintered body according to any of the second to fourth embodiments of the present disclosure. Thus, in the component body 23, the εᵣ and Qf values can be high and the TCC can be small.

Each of the ceramic green sheets 28 to 40 is produced using the glass-ceramic composition according to the first embodiment of the present disclosure. In particular, the ceramic green sheets 33 and 34, which directly contribute to the configuration exhibiting capacitance C, among the ceramic green sheets 28 to 40 are preferably produced using the glass-ceramic composition according to the first embodiment of the present disclosure. In other words, the ceramic green sheets 33 and 34 are each preferably made of the glass-ceramic sintered body according to any of the second to fourth embodiments of the present disclosure.

The electronic component for which the glass-ceramic composition and glass-ceramic sintered bodies of the present disclosure are used are not limited to the LC filter 21 shown in the drawing. For example, the glass-ceramic composition and glass-ceramic sintered bodies of the present disclosure are applicable to various multilayer ceramic substrates, such as multilayer ceramic substrates for multichip modules and multilayer ceramic substrates for hybrid ICs; various composite electronic components in which electronic components are mounted on any of these multilayer ceramic substrates; and various chip-type multilayer electronic components, such as chip-type multilayer capacitors and chip-type multilayer dielectric antennas.

The following contents are disclosed herein.

### Disclosure (1)

A glass-ceramic composition containing: glass containing Li₂O, MgO, SrO, B₂O₃, SiO₂, and ZnO; and aggregates, wherein, relative to 100% by weight of the glass-ceramic composition, a content of the glass is 9% by weight to 14% by weight, and the aggregates include 80% by weight to 86% by weight of ZrO₂, 2% by weight to 6% by weight of CaTiO₃, and 1% by weight to 4% by weight of at least one of BaCO₃ or Al₂O₃.

### Disclosure (2)

The glass-ceramic composition according to Disclosure (1), wherein the glass has a Li₂O content of 3% by weight to 15% by weight, a MgO content of 20% by weight to 50% by weight, a SrO content of 5% by weight to 25% by weight, a B₂O₃ content of 15% by weight to 30% by weight, a SiO₂ content of 10% by weight to 35% by weight, and a ZnO content of 6% by weight to 20% by weight.

### Disclosure (3)

An electronic component including a glass-ceramic layer made of a glass-ceramic sintered body formed by firing the glass-ceramic composition according to Disclosure (1) or (2).

### Disclosure (4)

The electronic component according to Disclosure (3), wherein the electronic component is an LC filter.

### Disclosure (5)

A glass-ceramic sintered body containing Zr, Ca, Ti, Ba, Li, Mg, Sr, B, Si, and Zn, wherein the glass-ceramic sintered body has a ZrO₂ content of 80% by weight to 86% by weight, a CaTiO₃ content of 2% by weight to 6% by weight, a BaO content of 0.78% by weight to 3.14% by weight, a Li₂O content of 0.3% by weight to 1.5% by weight, a MgO content of 2% by weight to 5% by weight, a SrO content of 0.5% by weight to 2.5% by weight, a B₂O₃ content of 1.5% by weight to 3% by weight, a SiO₂ content of 1% by weight to 3.5% by weight, and a ZnO content of 0.6% by weight to 2% by weight.

### Disclosure (6)

A glass-ceramic sintered body containing Zr, Ca, Ti, Al, Li, Mg, Sr, B, Si, and Zn, wherein the glass-ceramic sintered body has a ZrO₂ content of 80% by weight to 86% by weight, a CaTiO₃ content of 2% by weight to 6% by weight, an Al₂O₃ content of 1% by weight to 4% by weight, a Li₂O content of 0.3% by weight to 1.5% by weight, a MgO content of 2% by weight to 5% by weight, a SrO content of 0.5% by weight to 2.5% by weight, a B₂O₃ content of 1.5% by weight to 3% by weight, a SiO₂ content of 1% by weight to 3.5% by weight, and a ZnO content of 0.6% by weight to 2% by weight.

### Disclosure (7)

A glass-ceramic sintered body containing Zr, Ca, Ti, Ba, Al, Li, Mg, Sr, B, Si, and Zn, wherein the glass-ceramic sintered body has a ZrO₂ content of 80% by weight to 86% by weight, a CaTiO₃ content of 2% by weight to 6% by weight, a BaO content of 0.78% by weight to 2.35% by weight, an Al₂O₃ content of 1% by weight to 3.01% by weight, a Li₂O content of 0.3% by weight to 1.5% by weight, a MgO content of 2% by weight to 5% by weight, a SrO content of 0.5% by weight to 2.5% by weight, a B₂O₃ content of 1.5% by weight to 3% by weight, a SiO₂ content of 1% by weight to 3.5% by weight, and a ZnO content of 0.6% by weight to 2% by weight.

### Disclosure (8)

An electronic component including a glass-ceramic layer made of the glass-ceramic sintered body according to any one of Disclosures (5) to (7).

### Disclosure (9)

The electronic component according to Disclosure (8), wherein the electronic component is an LC filter.

### EXAMPLES

Hereinafter, an example more specifically disclosing the glass-ceramic composition and glass-ceramic sintered bodies of the present disclosure will be described. The present disclosure is not limited only to the example.

### (A) Production of Glass Powder

The following method was used to produce glass powders having the compositions shown in the following Table 1 as borosilicate glass powders to be contained in a glass-ceramic composition. First, glass raw material powders were mixed, placed in a Pt—Rh crucible, and melted at 1650° C. in an air atmosphere for 6 hours or more. Thereafter, the obtained melt was rapidly cooled to produce cullet. The cullet was coarsely ground, then placed in a container together with an organic solvent and PSZ balls (diameter: 5 mm), and mixed using a ball mill. By adjusting the grinding time during mixing using a ball mill, a glass powder having a median particle size of 1 to 2 μm was obtained. Here, the “median particle size” means the median particle size D50 measured by the laser diffraction/scattering method. In Table 1, the glass powders having a “glass symbol” marked with an asterisk (*) are glass powders having compositions that form a glass-ceramic sintered body outside the scope of the glass-ceramic sintered bodies of the present disclosure.

### (B) Production of Green Sheets

ZrO₂ powder having a specific surface area of 30 m²/g, CaTiO₃ powder having a specific surface area of 4 m²/g, BaCO₃ powder having a specific surface area of 2 m²/g, and Al₂O₃ powder having a specific surface area of 7 m²/g were prepared as aggregate (filler) components. The “specific surface area” here means a value measured by the BET method. Then, the aggregate component powders, glass powder, and a dispersant were placed in a toluene/ethanol mixed solvent in proportions shown in Table 2 below, and mixed using a ball mill with PSZ balls (diameter: 5 mm). Furthermore, a solution of a butyral-based binder in a toluene/ethanol mixed solvent and a plasticizer were added, followed by further mixing, so that the desired slurry was obtained. The slurry was molded on carrier films using a doctor blade and dried. Thereby, two types of green sheets with thicknesses of 15 μm and 50 μm were obtained.

### (C) Production and Evaluation of Evaluation Samples

Evaluation samples were produced and evaluated in the following manner.

### (1) Evaluation of Sinterability and Acid Resistance

Samples for evaluating the sinterability and acid resistance were prepared by the following procedure. Twenty 50-um-thick green sheets cut to a size of 78 mm×58 mm were stacked together and subjected to a hydrostatic press at 160 MPa to produce a compression-bonded body. The compression-bonded body was cut into individual pieces of 35 mm×6 mm, which were then fired in a reducing atmosphere at 980° C. for 180 minutes to obtain the target samples. In Table 2, sample numbers marked with * indicate samples that formed a sintered body having a composition outside the scope of the glass-ceramic sintered bodies of the present disclosure.

The fired samples were immersed in Super Check dye penetrant (Marktec Corporation) for 1 minute, then thoroughly rinsed with running water and dried in an oven at 120° C. for 120 minutes, followed by visual checking for coloring. Samples observed to have been colored were determined as insufficiently sintered ones and marked as x in Table 2, and were not subjected to the subsequent evaluation of acid resistance.

After the sinterability was checked, the weight of each sample was measured using an electronic balance. The sample was then placed in a 5-ml glass bottle filled with an acidic aqueous solution adjusted to pH 4 with sulfuric acid or the like. The glass bottle was capped and left in an oven at 73° C. for 24 hours. Thereafter, the sample was taken out, thoroughly rinsed with running water, and then dried in an oven at 120° C. for 120 minutes. The weight of the sample was then measured again to calculate the percent dissolution of the sample into the acidic aqueous solution according to the following formula. Samples with a percent dissolution of higher than 0.1% were determined to have poor acid resistance and marked as x in Table 2.

$$Percent dissolution ( \% ) = ( weight before dissolution test - weight after dissolution test ) / weight before dissolution test \times 100$$

### (2) Measurement of εᵣ (Relative Permittivity) and Qf Value (Reciprocal of Dielectric Loss×Frequency)

Samples for evaluation of the εᵣ and Qf value were produced by the following procedure. Six 50-um-thick green sheets cut to a size of 78 mm×58 mm were stacked together and subjected to a hydrostatic press at 160 MPa to produce a compression-bonded body. The compression-bonded body was cut into individual pieces of 42 mm×35 mm, which were then fired in a reducing atmosphere at 980° C. for 180 minutes to obtain the target samples. Samples with sample numbers evaluated as having poor sinterability or poor acid resistance were excluded from the evaluation of the εᵣ and Qf value.

The εᵣ and Q value (the reciprocal of dielectric loss) of the fired samples in the millimeter wave band (25 GHz) were measured by a TE₀₁₁ mode cavity resonator method in accordance with JIS R 1641. Two samples were subjected to the measurement for each level, and the average of the measurements was taken as the measurement value. Samples of a level at which the εᵣ was lower than 15 were excluded from the scope of the present disclosure. The Qf value was calculated according to the following formula, and samples of a level at which the Qf value was lower than 10000 GHz were excluded from the scope of the present disclosure.

$$Qf value ( GHz ) = Q value \times measurement frequency$$

### (3) Measurement of Rate of Change of Capacitance (TCC)

Samples for evaluating the TCC were prepared by the following procedure. A 15-μm-thick sheet was cut into 47 mm×24 mm sheets. An electrode paste containing Cu as its main component was applied to the front and back of each sheet by screen printing, followed by drying at 60° C. for 30 minutes. The paste was applied to form 3 mm×3 mm opposing electrode portions each including a lead-out electrode. Ten opposing electrode portions of the same shape were simultaneously formed in a single print. The printing positions were adjusted such that all of the opposing electrode portions were in the same position on the front and back of the sheet.

Next, a 50-μm-thick sheet was cut into 47 mm×24 mm sheets, of which eight sheets were stacked on one main surface of one of the printed and dried 15-μm-thick sheets and eight sheets were stacked on the other main surface of the sheet. The stack was then subjected to a hydrostatic press at 160 MPa to produce a compression-bonded body. The compression-bonded body was cut into individual pieces of 7.5 mm×5 mm such that the lead-out electrodes would be exposed at the ends. An end electrode paste containing Cu as its main component was applied to the ends of the individual pieces to cover the lead-out electrodes. Thereafter, the workpiece was fired in a reducing atmosphere at 980° C. for 180 minutes to obtain the target samples. Samples of the numbers evaluated as having poor sinterability or poor acid resistance were excluded from the evaluation of the TCC.

The TCC was measured by the following procedure. Ten sintered samples of each level were attached to a jig equipped with terminals in a thermostatic chamber, and capacitance was measured at 5° C. intervals in a temperature range of −50° C. to 100° C. using an LCR meter. The measurement conditions were a frequency of 1 kHz, a voltage of 1 V, and no DC bias.

Subsequently, the TCC from −40° C. to 20° C. and the TCC from 20° C. to 85° C. were calculated from the following respective formulas. In Table 2, a TCC value whose absolute value is maximum among 10 samples of each level is shown, and samples with an absolute value of more than 75 were excluded from the scope of the present disclosure.
Capacitance value at 20° C.: C0
Capacitance value at −40° C.: C1
Capacitance value at 85° C.: C2
TCC (ppm/° C.) from −40° C. to 20° C.=(C1−C0)/C0/(−40−20)×1000000
TCC (ppm/° C.) from 20° C. to 85° C.=(C2−C0)/C0/(85−20)×1000000

TABLE 1

| | Component percenrage | | | | | | |
|---|---|---|---|---|---|---|---|
| Glass | (% by weight) of glass | | | | | | |
| symbol | Li₂O | MgO | SrO | B₂O₃ | SiO₂ | ZnO | Note |
| G1* | 2.0 | 28.0 | 17.5 | 20.0 | 25.0 | 7.5 | |
| G2 | 3.0 | 27.0 | 17.5 | 20.0 | 25.0 | 7.5 | |
| G3 | 15.0 | 22.5 | 12.5 | 17.5 | 25.0 | 7.5 | |
| G4* | 16.0 | 21.5 | 12.5 | 17.5 | 25.0 | 7.5 | |
| G5* | 5.0 | 17.5 | 20.0 | 25.0 | 25.0 | 7.5 | |
| G6 | 5.0 | 20.0 | 17.5 | 25.0 | 25.0 | 7.5 | |
| G7 | 5.0 | 50.0 | 5.0 | 17.5 | 15.0 | 7.5 | |
| G8* | 5.0 | 52.5 | 2.5 | 17.5 | 15.0 | 7.5 | De- |
| | | | | | | | vitrification |
| G9 | 5.0 | 22.5 | 25.0 | 20.0 | 20.0 | 7.5 | |
| G10* | 5.0 | 21.5 | 26.0 | 20.0 | 20.0 | 7.5 | |
| G11* | 5.0 | 31.0 | 17.5 | 14.0 | 25.0 | 7.5 | De- |
| | | | | | | | vitrification |
| G12 | 5.0 | 30.0 | 17.5 | 15.0 | 25.0 | 7.5 | |
| G13 | 5.0 | 25.0 | 12.5 | 30.0 | 20.0 | 7.5 | |
| G14* | 5.0 | 24.0 | 12.5 | 31.0 | 20.0 | 7.5 | |
| G15* | 5.0 | 41.0 | 17.5 | 20.0 | 9.0 | 7.5 | De- |
| | | | | | | | vitrification |
| G16 | 5.0 | 40.0 | 17.5 | 20.0 | 10.0 | 7.5 | |
| G17 | 5.0 | 22.5 | 12.5 | 17.5 | 35.0 | 7.5 | |
| G18* | 5.0 | 21.5 | 12.5 | 17.5 | 36.0 | 7.5 | |
| G19* | 5.0 | 27.5 | 17.5 | 20.0 | 25.0 | 5.0 | |
| G20 | 5.0 | 26.5 | 17.5 | 20.0 | 25.0 | 6.0 | |
| G21 | 5.0 | 25.0 | 7.5 | 17.5 | 25.0 | 20.0 | |
| G22* | 5.0 | 24.0 | 7.5 | 17.5 | 25.0 | 21.0 | |
| G23 | 5.0 | 30.0 | 17.5 | 20.0 | 20.0 | 7.5 | |
| G24 | 5.0 | 27.5 | 15.0 | 20.0 | 25.0 | 7.5 | |
| G25 | 5.0 | 25.0 | 17.5 | 20.0 | 25.0 | 7.5 | |

TABLE 2

| | | | | | Glass component | | | | | | | |
|---|---|---|---|---|---|---|---|---|---|---|---|---|
| | Filler component | | | | Amount | | | | | | TCC | |
| Sample | (% by weight) | | | | (% by | | | | | Qf | (ppm/ | |
| No. | ZrO₂ | CaTiO₃ | BaCO₃ | Al₂O₃ | weight) | Type | Sinterability | resistance | εᵣ | (GHz) | ° C.) | Note |
| 1* | 84.0 | 4.0 | 0.0 | 2.0 | 10.0 | G1 | x | — | — | — | — | Sinterability |
| 2 | 84.0 | 4.0 | 0.0 | 2.0 | 10.0 | G2 | ○ | ○ | 16.2 | 11000 | 1 | |
| 3 | 84.0 | 4.0 | 0.0 | 2.0 | 10.0 | G3 | ○ | ○ | 16.3 | 10000 | 29 | |
| 4* | 84.0 | 4.0 | 0.0 | 2.0 | 10.0 | G4 | ○ | x | — | — | — | Acid resistance |
| 5* | 84.0 | 4.0 | 0.0 | 2.0 | 10.0 | G5 | ○ | ○ | 17.0 | 8000 | 14 | Qf |
| 6 | 84.0 | 4.0 | 0.0 | 2.0 | 10.0 | G6 | ○ | ○ | 17.0 | 14000 | 13 | |
| 7 | 84.0 | 4.0 | 0.0 | 2.0 | 10.0 | G7 | ○ | ○ | 16.3 | 20000 | 11 | |
| 8 | 84.0 | 4.0 | 0.0 | 2.0 | 10.0 | G9 | ○ | ○ | 16.1 | 14000 | 1 | |
| 9* | 84.0 | 4.0 | 0.0 | 2.0 | 10.0 | G10 | ○ | ○ | 16.0 | 8000 | −2 | Qf |
| 10 | 84.0 | 4.0 | 0.0 | 2.0 | 10.0 | G12 | ○ | ○ | 16.1 | 18000 | 8 | |
| 11 | 84.0 | 4.0 | 0.0 | 2.0 | 10.0 | G13 | ○ | ○ | 16.2 | 10000 | 16 | |
| 12* | 84.0 | 4.0 | 0.0 | 2.0 | 10.0 | G14 | ○ | x | — | — | — | Acid resistance |
| 13 | 84.0 | 4.0 | 0.0 | 2.0 | 10.0 | G16 | ○ | ○ | 16.3 | 14000 | 25 | |
| 14 | 84.0 | 4.0 | 0.0 | 2.0 | 10.0 | G17 | ○ | ○ | 16.1 | 11000 | 4 | |
| 15* | 84.0 | 4.0 | 0.0 | 2.0 | 10.0 | G18 | x | — | — | — | — | Sinterability |
| 16* | 84.0 | 4.0 | 0.0 | 2.0 | 10.0 | G19 | ○ | ○ | 16.2 | 7000 | 16 | Qf |
| 17 | 84.0 | 4.0 | 0.0 | 2.0 | 10.0 | G20 | ○ | ○ | 16.3 | 12000 | 17 | |
| 18 | 84.0 | 4.0 | 0.0 | 2.0 | 10.0 | G21 | ○ | ○ | 16.0 | 10000 | 12 | |
| 19* | 84.0 | 4.0 | 0.0 | 2.0 | 10.0 | G22 | ○ | x | — | — | — | Acid resistance |
| 20 | 84.0 | 4.0 | 0.0 | 2.0 | 10.0 | G23 | ○ | ○ | 16.2 | 20000 | −1 | |
| 21 | 84.0 | 4.0 | 0.0 | 2.0 | 10.0 | G24 | ○ | ○ | 16.3 | 21000 | 16 | |
| 22 | 84.0 | 4.0 | 0.0 | 2.0 | 10.0 | G25 | ○ | ○ | 16.3 | 22000 | 6 | |
| 23* | 86.5 | 4.0 | 0.0 | 2.0 | 7.5 | G25 | x | — | — | — | — | Sinterability |
| 24 | 85.0 | 4.0 | 0.0 | 2.0 | 9.0 | G25 | ○ | ○ | 16.5 | 21000 | 4 | |
| 25 | 81.5 | 4.0 | 0.0 | 2.0 | 12.5 | G25 | ○ | ○ | 15.8 | 17000 | 39 | |
| 26 | 80.0 | 4.0 | 0.0 | 2.0 | 14.0 | G25 | ○ | ○ | 15.2 | 14000 | 42 | |
| 27* | 79.0 | 4.0 | 0.0 | 2.0 | 15.0 | G25 | ○ | ○ | 14.9 | 12000 | 60 | εᵣ |
| 28* | 88.0 | 0.0 | 0.0 | 2.0 | 10.0 | G25 | x | — | — | — | — | Sinterability |
| 29 | 86.0 | 2.0 | 0.0 | 2.0 | 10.0 | G25 | ○ | ○ | 15.2 | 22000 | 30 | |
| 30 | 82.0 | 6.0 | 0.0 | 2.0 | 10.0 | G25 | ○ | ○ | 17.7 | 20000 | −60 | |
| 31* | 80.0 | 8.0 | 0.0 | 2.0 | 10.0 | G25 | ○ | ○ | 20.0 | 16000 | −125 | TCC |
| 32* | 86.0 | 4.0 | 0.0 | 0.0 | 10.0 | G25 | ○ | x | — | — | — | Acid resistance |
| 33 | 85.0 | 4.0 | 1.0 | 0.0 | 10.0 | G25 | ○ | ○ | 17.8 | 22000 | 40 | |
| 34 | 84.0 | 4.0 | 2.0 | 0.0 | 10.0 | G25 | ○ | ○ | 17.8 | 20000 | 63 | |
| 35 | 82.0 | 4.0 | 4.0 | 0.0 | 10.0 | G25 | ○ | ○ | 17.9 | 13000 | 75 | |
| 36* | 80.0 | 4.0 | 6.0 | 0.0 | 10.0 | G25 | ○ | ○ | 17.5 | 9000 | 80 | Qf, TCC |
| 37 | 85.0 | 4.0 | 0.0 | 1.0 | 10.0 | G25 | ○ | ○ | 17.2 | 22000 | 3 | |
| 38 | 82.0 | 4.0 | 0.0 | 4.0 | 10.0 | G25 | ○ | ○ | 15.2 | 19000 | 34 | |
| 39* | 80.0 | 4.0 | 0.0 | 6.0 | 10.0 | G25 | ○ | ○ | 14.0 | 15000 | 65 | εᵣ |
| 40 | 84.0 | 4.0 | 1.0 | 1.0 | 10.0 | G25 | ○ | ○ | 17.1 | 21000 | 35 | |
| 41 | 83.0 | 4.0 | 1.0 | 2.0 | 10.0 | G25 | ○ | ○ | 16.2 | 19000 | 14 | |
| 42 | 82.0 | 4.0 | 1.0 | 3.0 | 10.0 | G25 | ○ | ○ | 15.4 | 18000 | 26 | |
| 43 | 83.0 | 4.0 | 2.0 | 1.0 | 10.0 | G25 | ○ | ○ | 17.2 | 19000 | 43 | |
| 44 | 82.0 | 4.0 | 2.0 | 2.0 | 10.0 | G25 | ○ | ○ | 16.7 | 17000 | 23 | |
| 45 | 82.0 | 4.0 | 3.0 | 1.0 | 10.0 | G25 | ○ | ○ | 17.0 | 15000 | 51 | |

Table 1 shows the component percentages of the glass powders. The compositions G8, G11, and G15 marked with * suffered from a phenomenon in which part of the glass crystallized, i.e., devitrification, and thus were not subjected to any further evaluation. In addition, the other compositions marked with * did not achieve the desired characteristics when fired together with fillers.

Table 2 shows a list of the evaluation results of each sample. As described above, samples of the numbers marked with * are those that formed a sintered body outside the scope of the glass-ceramic sintered bodies of the present disclosure. The samples of the other numbers were determined to satisfy the characteristics below.
Sinterable at a temperature of 1000° C. or lower
Excellent acid resistance
εᵣ of 15 or higher
Qf value of 10000 or higher
Absolute values of TCC from −40° C. to 20° C. and TCC from 20° C. to 85° C. of 75 ppm/° C. or less

The samples of the numbers marked with * did not satisfy the characteristics above due to the factors below.
Sample No. 1: The sinterability was low (poor) since Glass G1 containing less than 3% by weight of Li₂O was used.
Sample No. 4: The acid resistance was low (poor) since Glass G4 containing more than 15% by weight of Li₂O was used.
Sample No. 5: The Qf value was low since Glass G5 containing 20% by weight or less of MgO was used.
Sample No. 9: The Qf value was low since Glass G10 containing more than 25% by weight of SrO was used.
Sample No. 12: The acid resistance was low (poor) since Glass G14 containing more than 30% by weight of B₂O₃ Was used.
Sample No. 15: The sinterability was low (poor) since Glass G18 containing more than 35% by weight of SiO₂ was used.
Sample No. 16: The Qf value was low since Glass G19 containing less than 6% by weight of ZnO was used.
Sample No. 19: The acid resistance was low (poor) since Glass G22 containing more than 20% by weight of ZnO was used.
Sample No. 23: The sinterability was low (poor) since the amount of Glass G25 added was less than 9% by weight.
Sample No. 27: The εᵣ was low since the amount of Glass G25 added was more than 14% by weight.
Sample No. 28: The sinterability was low (poor) since the amount of CaTiO₃ added was less than 2% by weight.
Sample No. 31: The absolute value of the TCC was large (to the negative side) since the amount of CaTiO₃ added was more than 6% by weight.
Sample No. 32: The acid resistance was low (poor) since the amount of at least one of BaCO₃ or Al₂O₃ added was less than 1% by weight.
Sample No. 36: The Qf value was low and the TCC was large since the amount of BaCO₃ added was more than 4% by weight.
Sample No. 39: The εᵣ was low since the amount of Al₂O₃ added was more than 4% by weight.

The results above show that glass-ceramic compositions having the following composition form a sintered body having a high relative permittivity and a high Qf value and a small rate of change of capacitance.

### Preparation Composition

ZrO₂ (80 to 86% by weight)/CaTiO₃ (2 to 6% by weight)/at least one of BaCO₃ or Al₂O₃ (1 to 4% by weight)/glass (9 to 14% by weight)
   Glass composition
Li₂O (3 to 15% by weight)/MgO (20 to 50% by weight)/SrO (5 to 25% by weight)/B₂O₃ (15 to 30% by weight)/SiO₂ (10 to 35% by weight)/ZnO (6 to 20% by weight)

For the examples of the glass-ceramic composition of the present disclosure, the preparation composition (charged composition) before firing is shown in Table 2. However, since BaCO₃ is present as BaO after firing, the percentage of each component after firing was determined by calculation. The component percentages for each sample number are shown in Table 3 below.

Although MgO and SiO₂ may partially react to form Mg₂SiO₄, they are considered equivalent here based on the reaction formula (1) above.

Tables 2 and 3 show that fired glass-ceramics (glass-ceramic sintered bodies) having any of the following compositions materialize a glass-ceramic sintered body having a high relative permittivity, a high Qf value, and a small rate of change of capacitance.

### Composition of Sintered Body

ZrO₂ (80 to 86% by weight)/CaTiO₃ (2 to 6% by weight)/BaO (0.78 to 3.14% by weight)/Li₂O (0.3 to 1.5% by weight)/MgO (2 to 5% by weight)/SrO (0.5 to 2.5% by weight)/B₂O₃ (1.5 to 3% by weight)/SiO₂(1 to 3.5% by weight)/ZnO (0.6 to 2 weight)
ZrO₂ (80 to 86% by weight)/CaTiO₃ (2 to 6% by weight)/Al₂O₃ (1 to 4% by weight)/Li₂O (0.3 to 1.5% by weight)/MgO (2 to 5% by weight)/SrO (0.5 to 2.5% by weight)/B₂O₃ (1.5 to 3% by weight)/SiO₂ (1 to 3.5% by weight)/ZnO (0.6 to 2% by weight)
ZrO₂ (80 to 86% by weight)/CaTiO₃ (2 to 6% by weight)/BaO (0.78 to 2.35% by weight)/Al₂O₃ (1 to 3.01% by weight)/Li₂O (0.3 to 1.5% by weight)/MgO (2 to 5% by weight)/SrO (0.5 to 2.5% by weight)/B₂O₃ (1.5 to 3% by weight)/SiO₂ (1 to 3.5% by weight)/ZnO (0.6 to 2% by weight)

TABLE 3

| Sample | Composition of sintered body (% by weight) | | | | | | | | | |
|---|---|---|---|---|---|---|---|---|---|---|
| No. | ZrO₂ | CaTiO₃ | BaC | Al₂O₃ | Li₂O | MgO | SrO | B₂O₃ | SiO₂ | ZnO |
| 1* | 84.00 | 4.00 | 0.00 | 2.00 | 0.20 | 2.80 | 1.75 | 2.00 | 2.50 | 0.75 |
| 2 | 84.00 | 4.00 | 0.00 | 2.00 | 0.30 | 2.70 | 1.75 | 2.00 | 2.50 | 0.75 |
| 3 | 84.00 | 4.00 | 0.00 | 2.00 | 1.50 | 2.25 | 1.25 | 1.75 | 2.50 | 0.75 |
| 4* | 84.00 | 4.00 | 0.00 | 2.00 | 1.60 | 2.15 | 1.25 | 1.75 | 2.50 | 0.75 |
| 5* | 84.00 | 4.00 | 0.00 | 2.00 | 0.50 | 1.75 | 2.00 | 2.50 | 2.50 | 0.75 |
| 6 | 84.00 | 4.00 | 0.00 | 2.00 | 0.50 | 2.00 | 1.75 | 2.50 | 2.50 | 0.75 |
| 7 | 84.00 | 4.00 | 0.00 | 2.00 | 0.50 | 5.00 | 0.50 | 1.75 | 1.50 | 0.75 |
| 8 | 84.00 | 4.00 | 0.00 | 2.00 | 0.50 | 2.25 | 2.50 | 2.00 | 2.00 | 0.75 |
| 9* | 84.00 | 4.00 | 0.00 | 2.00 | 0.50 | 2.15 | 2.60 | 2.00 | 2.00 | 0.75 |
| 10 | 84.00 | 4.00 | 0.00 | 2.00 | 0.50 | 3.00 | 1.75 | 1.50 | 2.50 | 0.75 |
| 11 | 84.00 | 4.00 | 0.00 | 2.00 | 0.50 | 2.50 | 1.25 | 3.00 | 2.00 | 0.75 |
| 12* | 84.00 | 4.00 | 0.00 | 2.00 | 0.50 | 2.40 | 1.25 | 3.10 | 2.00 | 0.75 |
| 13 | 84.00 | 4.00 | 0.00 | 2.00 | 0.50 | 4.00 | 1.75 | 2.00 | 1.00 | 0.75 |
| 14 | 84.00 | 4.00 | 0.00 | 2.00 | 0.50 | 2.25 | 1.25 | 1.75 | 3.50 | 0.75 |
| 15* | 84.00 | 4.00 | 0.00 | 2.00 | 0.50 | 2.15 | 1.25 | 1.75 | 3.60 | 0.75 |
| 16* | 84.00 | 4.00 | 0.00 | 2.00 | 0.50 | 2.75 | 1.75 | 2.00 | 2.50 | 0.50 |
| 17 | 84.00 | 4.00 | 0.00 | 2.00 | 0.50 | 2.65 | 1.75 | 2.00 | 2.50 | 0.60 |
| 18 | 84.00 | 4.00 | 0.00 | 2.00 | 0.50 | 2.50 | 0.75 | 1.75 | 2.50 | 2.00 |
| 19* | 84.00 | 4.00 | 0.00 | 2.00 | 0.50 | 2.40 | 0.75 | 1.75 | 2.50 | 2.10 |
| 20 | 84.00 | 4.00 | 0.00 | 2.00 | 0.50 | 3.00 | 1.75 | 2.00 | 2.00 | 0.75 |
| 21 | 84.00 | 4.00 | 0.00 | 2.00 | 0.50 | 2.75 | 1.50 | 2.00 | 2.50 | 0.75 |
| 22 | 84.00 | 4.00 | 0.00 | 2.00 | 0.50 | 2.50 | 1.75 | 2.00 | 2.50 | 0.75 |
| 23* | 86.50 | 4.00 | 0.00 | 2.00 | 0.38 | 1.88 | 1.31 | 1.50 | 1.88 | 0.56 |
| 24 | 85.00 | 4.00 | 0.00 | 2.00 | 0.45 | 2.25 | 1.58 | 1.80 | 2.25 | 0.68 |
| 25 | 81.50 | 4.00 | 0.00 | 2.00 | 0.63 | 3.13 | 2.19 | 2.50 | 3.13 | 0.94 |
| 26 | 80.00 | 4.00 | 0.00 | 2.00 | 0.70 | 3.50 | 2.45 | 2.80 | 3.50 | 1.05 |
| 27* | 79.00 | 4.00 | 0.00 | 2.00 | 0.75 | 3.75 | 2.63 | 3.00 | 3.75 | 1.13 |
| 28* | 88.00 | 0.00 | 0.00 | 2.00 | 0.50 | 2.50 | 1.75 | 2.00 | 2.50 | 0.75 |
| 29 | 86.00 | 2.00 | 0.00 | 2.00 | 0.50 | 2.50 | 1.75 | 2.00 | 2.50 | 0.75 |
| 30 | 82.00 | 6.00 | 0.00 | 2.00 | 0.50 | 2.50 | 1.75 | 2.00 | 2.50 | 0.75 |
| 31* | 80.00 | 8.00 | 0.00 | 2.00 | 0.50 | 2.50 | 1.75 | 2.00 | 2.50 | 0.75 |
| 32* | 86.00 | 4.00 | 0.00 | 0.00 | 0.50 | 2.50 | 1.75 | 2.00 | 2.50 | 0.75 |
| 33 | 85.19 | 4.01 | 0.78 | 0.00 | 0.50 | 2.51 | 1.75 | 2.00 | 2.51 | 0.75 |
| 34 | 84.38 | 4.02 | 1.56 | 0.00 | 0.50 | 2.51 | 1.76 | 2.01 | 2.51 | 0.75 |
| 35 | 82.74 | 4.04 | 3.14 | 0.00 | 0.50 | 2.52 | 1.77 | 2.02 | 2.52 | 0.76 |
| 36* | 81.08 | 4.05 | 4.73 | 0.00 | 0.49 | 2.53 | 1.7 | 2.03 | 2.53 | 0.76 |
| 37 | 85.00 | 4.00 | 0.00 | 1.00 | 0.50 | 2.50 | 1.75 | 2.00 | 2.50 | 0.75 |
| 38 | 82.00 | 4.00 | 0.00 | 4.00 | 0.50 | 2.50 | 1.75 | 2.00 | 2.50 | 0.75 |
| 39* | 80.00 | 4.00 | 0.00 | 6.00 | 0.50 | 2.50 | 1.75 | 2.00 | 2.50 | 0.75 |
| 40 | 84.19 | 4.01 | 0.78 | 1.00 | 0.50 | 2.51 | 1.75 | 2.00 | 2.51 | 0.75 |
| 41 | 83.19 | 4.01 | 0.78 | 2.00 | 0.50 | 2.51 | 1.75 | 2.00 | 2.51 | 0.75 |
| 42 | 82.18 | 4.0 | 0.78 | 3.01 | 0.50 | 2.51 | 1.75 | 2.00 | 2.51 | 0.75 |
| 43 | 83.37 | 4.02 | 1.56 | 1.00 | 0.50 | 2.51 | 1.76 | 2.01 | 2.51 | 0.75 |
| 44 | 82.37 | 4.02 | 1.56 | 2.01 | 0.50 | 2.51 | 1.76 | 2.01 | 2.51 | 0.75 |
| 45 | 82.55 | 4.03 | 2.35 | 1.01 | 0.50 | 2.52 | 1.76 | 2.01 | 2.52 | 0.76 |

### REFERENCE SIGNS LIST

43, 45, 46, 50, 52, 56, 57, 59 via hole conductor
21 LC filter
23 component body
24 to 27 terminal electrode
28 to 40 ceramic green sheet
41, 44, 58, 60 coil pattern
42, 48, 49, 54, 55, 61 lead-out pattern
47, 51, 53 capacitor pattern

1. A glass-ceramic composition comprising:
glass containing Li₂O, MgO, SrO, B₂I₃, SiO₂, and ZnO; and
aggregates,
wherein, relative to 100% by weight of the glass-ceramic composition,
a content of the glass is 9% by weight to 14% by weight, and
the aggregates include 80% by weight to 86% by weight of ZrO₂, 2% by weight to 6% by weight of CaTiO₃, and 1% by weight to 4% by weight of at least one of BaCO₃ or Al₂O₃.

2. The glass-ceramic composition according to claim 1, wherein the glass has
a Li₂O content of 3% by weight to 15% by weight,
a MgO content of 20% by weight to 50% by weight,
a SrO content of 5% by weight to 25% by weight,
a B₂O₃ content of 15% by weight to 30% by weight,
a SiO₂ content of 10% by weight to 35% by weight, and
a ZnO content of 6% by weight to 20% by weight.

3. The glass-ceramic composition according to claim 1, wherein
the ZrO₂ content is 82% by weight to 85% by weight,
the CaTiO₃ content is 4% by weight to 6% by weight, and
the content of the at least one of the BaCO₃ or the Al₂O₃ is 1% by weight to 2% by weight.

4. The glass-ceramic composition according to claim 1, wherein the content of the glass is 9% by weight to 10% by weight.

5. The glass-ceramic composition according to claim 1, wherein the glass has
a Li₂O content of 3% by weight to 7% by weight,
a MgO content of 25% by weight to 50% by weight,
a SrO content of 5% by weight to 17.5% by weight,
a B₂O₃ content of 15% by weight to 20% by weight,
a SiO₂ content of 15% by weight to 25% by weight, and
a ZnO content of 6% by weight to 9% by weight.

6. An electronic component comprising a glass-ceramic layer made of a glass-ceramic sintered body that is a fired product of the glass-ceramic composition according to claim 1.

7. The electronic component according to claim 6, wherein the electronic component is an LC filter.

8. A glass-ceramic sintered body comprising Zr, Ca, Ti, Ba, Li, Mg, Sr, B, Si, and Zn,
wherein the glass-ceramic sintered body has
a ZrO₂ content of 80% by weight to 86% by weight,
a CaTiO₃ content of 2% by weight to 6% by weight,
a BaO content of 0.78% by weight to 3.14% by weight,
a Li₂O content of 0.3% by weight to 1.5% by weight,
a MgO content of 2% by weight to 5% by weight,
a SrO content of 0.5% by weight to 2.5% by weight,
a B₂O₃ content of 1.5% by weight to 3% by weight,
a SiO₂ content of 1% by weight to 3.5% by weight, and
a ZnO content of 0.6% by weight to 2% by weight.

9. The glass-ceramic sintered body according to claim 8, wherein
the BaO content is 0.78% by weight to 1.56% by weight,
the Li₂O content is 0.3% by weight to 0.7% by weight,
the MgO content is 2.5% by weight to 5% by weight,
the SrO content is 0.5% by weight to 1.75% by weight,
the B₂O₃ content is 1.5% by weight to 2% by weight,
the SiO₂ content is 1.5% by weight to 2.5% by weight, and
the ZnO content is 0.6% by weight to 0.9% by weight.

10. An electronic component comprising a glass-ceramic layer made of the glass-ceramic sintered body according to claim 8.

11. The electronic component according to claim 10, wherein the electronic component is an LC filter.

12. A glass-ceramic sintered body comprising Zr, Ca, Ti, Al, Li, Mg, Sr, B, Si, and Zn,
wherein the glass-ceramic sintered body has
a ZrO₂ content of 80% by weight to 86% by weight,
a CaTiO₃ content of 2% by weight to 6% by weight,
an Al₂O₃ content of 1% by weight to 4% by weight,
a Li₂O content of 0.3% by weight to 1.5% by weight,
a MgO content of 2% by weight to 5% by weight,
a SrO content of 0.5% by weight to 2.5% by weight,
a B₂O₃ content of 1.5% by weight to 3% by weight,
a SiO₂ content of 1% by weight to 3.5% by weight, and
a ZnO content of 0.6% by weight to 2% by weight.

13. The glass-ceramic sintered body according to claim 12, wherein
the Al₂O₃ content is 1% by weight to 2% by weight,
the Li₂O content is 0.3% by weight to 0.7% by weight,
the MgO content is 2.5% by weight to 5% by weight,
the SrO content is 0.5% by weight to 1.75% by weight,
the B₂O₃ content is 1.5% by weight to 2% by weight,
the SiO₂ content is 1.5% by weight to 2.5% by weight, and
the ZnO content is 0.6% by weight to 0.9% by weight.

14. An electronic component comprising a glass-ceramic layer made of the glass-ceramic sintered body according to claim 12.

15. The electronic component according to claim 14, wherein the electronic component is an LC filter.

16. A glass-ceramic sintered body comprising Zr, Ca, Ti, Ba, Al, Li, Mg, Sr, B, Si, and Zn,
wherein the glass-ceramic sintered body has
a ZrO₂ content of 80% by weight to 86% by weight,
a CaTiO₃ content of 2% by weight to 6% by weight,
a BaO content of 0.78% by weight to 2.35% by weight,
an Al₂O₃ content of 1% by weight to 3.01% by weight,
a Li₂O content of 0.3% by weight to 1.5% by weight,
a MgO content of 2% by weight to 5% by weight,
a SrO content of 0.5% by weight to 2.5% by weight,
a B₂O₃ content of 1.5% by weight to 3% by weight,
a SiO₂ content of 1% by weight to 3.5% by weight, and
a ZnO content of 0.6% by weight to 2% by weight.

17. The glass-ceramic sintered body according to claim 16, wherein
the BaO content is 0.78% by weight to 1.56% by weight,
the Al₂O₃ content is 1% by weight to 2% by weight,
the Li₂O content is 0.3% by weight to 0.7% by weight,
the MgO content is 2.5% by weight to 5% by weight,
the SrO content is 0.5% by weight to 1.75% by weight,
the B₂O₃ content is 1.5% by weight to 2% by weight,
the SiO₂ content is 1.5% by weight to 2.5% by weight, and
the ZnO content is 0.6% by weight to 0.9% by weight.

18. The glass-ceramic sintered body according to claim 16, wherein
the BaO content is 0.78% by weight to 1.5% by weight,
the Al₂O₃ content is 1% by weight to 1.5% by weight,
the Li₂O content is 0.3% by weight to 0.7% by weight,
the MgO content is 2.5% by weight to 5% by weight,
the SrO content is 0.5% by weight to 1.75% by weight,
the B₂O₃ content is 1.5% by weight to 2% by weight,
the SiO₂ content is 1.5% by weight to 2.5% by weight, and
the ZnO content is 0.6% by weight to 0.9% by weight.

19. An electronic component comprising a glass-ceramic layer made of the glass-ceramic sintered body according to claim 16.

20. The electronic component according to claim 19, wherein the electronic component is an LC filter.
